(19) United States
(12) Patent Application Publication
(10) Pub. No.: US 2004/0251532 A1
(43) Pub. Date: Dec. 16, 2004

(54) Chip package structure

(76) Inventors: Potter Chien, Hsinchu Hsien (TW); Dennis Pai, Hsinchu Hsien (TW)

Correspondence Address: PRO-TECHTOR INTERNATIONAL, 20775 Norada Court, Saratoga, CA, 95070-3018, US

(21) Appl. No.: 10/458,941

(22) Filed: Jun. 10, 2003

(51) Int. Cl. H01L 23/48

(52) U.S. Cl. 257/690

(57) ABSTRACT

A chip package structure includes a substrate, a chip, a plurality of wires and an expose resin. The substrate is formed with a top surface, a bottom surface, and a long slot penetrating from the top surface to the bottom surface, at the periphery of the long slot of the bottom surface is forming with a plurality of connect points and at least a first ground point. The chip, on which at least a second ground point is formed at the periphery of the chip, and a plurality of bonding pads is located on the central of the chip, a conductive glue is printed to the periphery the chip, and electrically connected to the second ground point, since the chip mounted on the upper surface of the substrate, the plurality of bonding pads of the chip are exposed via the long slot of the substrate. Also a part of conductive glue exposed from the long slot of the substrate, The plurality of wires, which are located within the long slot of the substrate, each of which has first terminal and second terminal, wherein the first terminal is electrically to the bonding pads and conductive glue, and second terminal is electrically connected to the connect points and first ground point of the substrate. The glue layer is sealed onto the chip and filled into the long slot of the substrate.

### BACKGROUND OF THE INVENTION

1. Field of the Invention

The invention relates to a chip package structure, in particular, to a chip package, which is enhanced the applied field of chip package.

2. Description of the Related Art

Please referring to FIG. 1 and FIG. 2, a schematic illustrate showing a conventional a chip package structure includes a substrate 10, a chip 12, a plurality of wires 14 and an expose resin 16. The substrate 10 has a plurality of connected points 18 and at least a first ground points 20. The chip 12 is forming with a plurality of bonding pads 22 and at least a second ground point 24. The chip 12 is arranged on the substrate 10. The plurality of wires 14, each of which are electrically connected the bonding pads 22 of the chip 21 to the connected points 18 of the substrate 11, and are electrically connected the second ground 24 of the chip 12 to the first connected point 20. The expose resin 16 is covered the chip 12 and a plurality of wire 14 for protecting the chip 12 and a plurality of wires, then the package structure is performed. Consequently, the overall package volume of the chip may be enlarged, thereby causing the inconvenience in usage.

Please referring to FIG. 3 and FIG. 4, a schematic illustrate showing further a conventional a chip package structure, which may be reduced the volume of the package, includes a substrate 26, a chip 38, a plurality of 44 and expose resin 46. The substrate 26 has a top surface 28, a bottom surface 30 and a through slot 32 penetrate from the top surface 28 to the bottom surface 30, the bottom surface 30 is formed with a plurality of connect point 34 and at least a first ground point 36 at the periphery of the through slot 36. The chip 38 has a plurality of bonding pads 40 and at least a second ground point 36. The plurality of wires 44, which are arranged within through slot 32 for electrically connecting the bonding pads 40 of the chip 38 to the connect points 34 of the substrste 26, and electrically connecting the second ground point 42 of the chip 38 to first ground connect 36 of the substrate 26. The expose resin 46 is covered on the chip 38 and the through slot 32 of the substrate 26 for protecting the chip 39 and a plurality of wires 44.

Therefore, according to the above-mentioned structure may be reduced the package volume, but, if the second ground point 42 of the chip 38 is formed at the periphery of the chip 38, the ground point 42 shall be covered by the substrate 26, so that the wires 44 can not performed bonding by way of the above-mentioned of structure.

To solve the above-mentioned problems, it is necessary for the inventor to provide a chip package structure, in order to enhanced the applied field of a chip package

### SUMMARY OF THE INVENTION

It is therefore an object of the invention to provide a chip package structure capable of enhancing the applied field of a chip package.

To achieve the above-mentioned objects, the invention is characterized in that the chip is coated with a conductive resin for electrically connecting to the second ground point of the chip, so as to the wire may be electrically connected the conductive resin, thus, the second ground point may be electrically connected to the first ground point by way of the wires.

According to one aspect of the invention, a chip package structure includes a substrate, a chip, a plurality of wires and an expose resin. The substrate is formed with a top surface, a bottom surface, and a long slot penetrating from the top surface to the bottom surface, at the periphery of the long slot of the bottom surface is forming with a plurality of connect points and at least a first ground point. The chip, on which at least a second ground point is formed at the periphery of the chip, and a plurality of bonding pads is located on the central of the chip, a conductive glue is printed to the periphery the chip, and electrically connected to the second ground point, since the chip mounted on the upper surface of the substrate, the plurality of bonding pads of the chip are exposed via the long slot of the substrate. Also a part of conductive glue exposed from the long slot of the substrate, The plurality of wires, which are located within the long slot of the substrate, each of which has first terminal and second terminal, wherein the first terminal is electrically to the bonding pads and conductive glue, and second terminal is electrically connected to the connect points and first ground point of the substrate. A glue layer is sealed onto the chip and filled into the long slot of the substrate for protecting the chip and the plurality of wires.

Thus, the chip package structure may be enhanced the applied field of a chip package.

### BRIEF DESCRIPTION OF THE DRAWINGS

FIG. 1 is a schematic illustrate showing a chip package structure.

FIG. 2 is a top view of the FIG. 1.

FIG. 3 is a cross-sectional view showing further a conventional a chip package structure.

FIG. 4 is top view of the FIG. 3.

FIG. 5 is a cross-sectional showing a chip package structure in accordance with the present invention.

FIG. 6 is a top view of the FIG. 5 of the present invention.

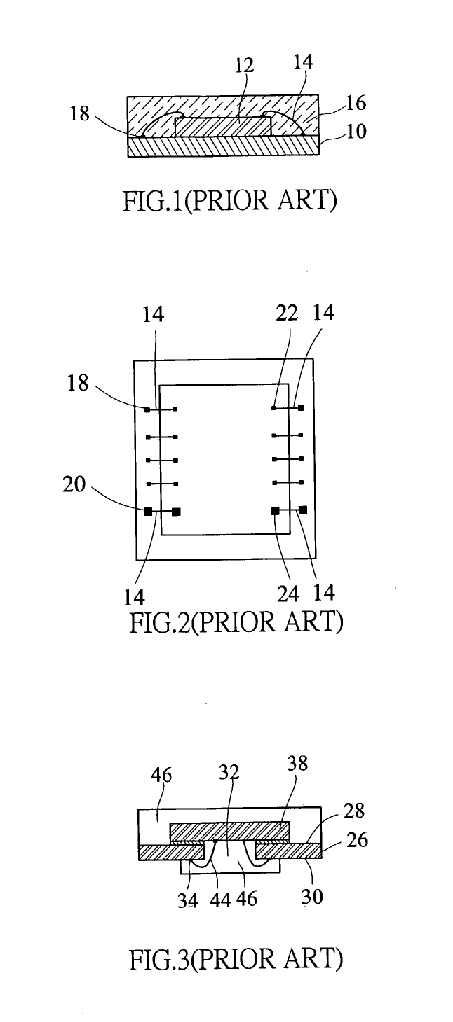

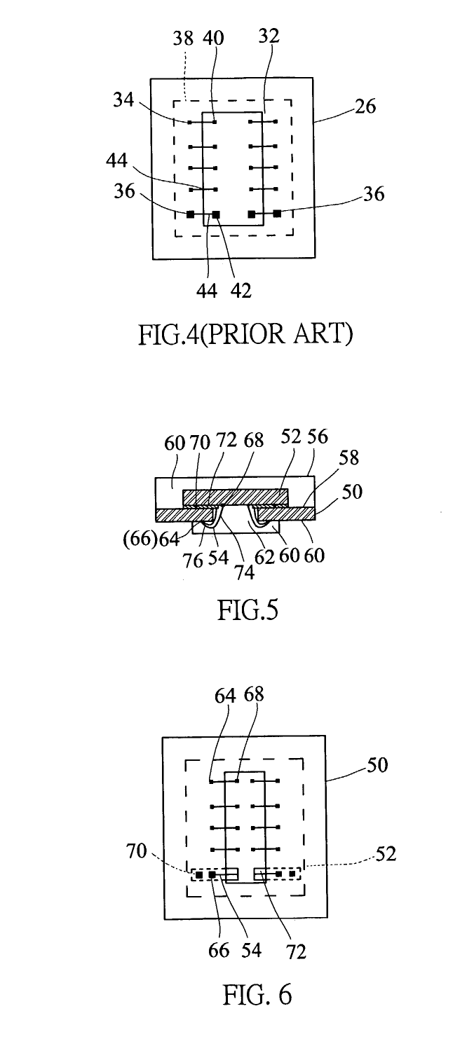

### DETAIL DESCRIPTION OF THE INVENTION

Please referring to FIG. 5 and FIG. 6, a chip package structure of the present invention includes a substrate 50, a chip 52, a plurality of wires 54 and a glue layer 56.

The substrate 50 has a top surface 58, a bottom surface 60, and a long slot 62 penetrating from the top surface 58 to the bottom surface 60, at the periphery of the long slot 62 of the bottom surface 60 is forming with a plurality of connect points 64 and at least a first ground point 66 (VSS). In the embodiment of the substrate 50 of the present invention have two first ground point 66 (VSS).

The chip 52 may be a DRAM, on which at least a second ground point 70 (VSS) is formed at the periphery of the chip 52, and a plurality of bonding pads 68 are located on the central of the chip 52, a conductive glue 72 is printed to the periphery of the chip 52 and is electrically connected to the second ground point 70 (VSS), since the chip 52 is mounted on the upper surface 58 of the substrate 50, the plurality of bonding pads 68 of the chip 52 are exposed via the long slot 62 of the substrate 50, also a part of conductive glue 72 is exposed from the long slot 62 of the substrate 50. In the embodiment of the substrate 50 of the present invention have two first ground point 66 (VSS).

Each of wires 54, which are located within the long slot 62 of the substrate 50, each of which have a first terminal 74 and a second terminals 76, wherein the first terminals 66 are electrically to the bonding pads 62 of the chip 52 and conductive glue 72, and second terminals 76 are electrically connected to the connect points 64 of the substrate 50 and first ground point 66 of the substrate, respectively. Thus, signals from the chip 52 may be transmitted to the substrate 50, and the second ground point 70 of the chip 52 may be electrically connected to the first ground point 66 of the substrate 50 via conductive glue 72.

The glue layer 56 is sealed on the chip 52 and filled into the long slot 62 of the substrate 50 for protecting the chip 52 and the plurality of wires 54.

As a result, the package structure has the following advantages.

1. Since while the second ground point 70 of the ship 52 is designed to another position of the chip 52, so as to second ground point 70 of the chip 50 is covered by substrate 50, the second ground point 70 of the chip 50 may be electrically connected to the wires 54 by way of the conductive glue 72, therefore, the chip 52 of the present invention may be reduced the volume of the package via the package structure.

2. Since the present invention may be enhanced the applied field of chip package.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A chip package structure, comprising
a substrate formed with a top surface, a bottom surface, and a long slot penetrating from the top surface to the bottom surface, at the periphery of the long slot of the bottom surface forming with a plurality of connect points and at least a first ground point;
a chip, on which at least a second ground point is formed at the periphery of the chip, and a plurality of bonding pads are located on the central of the chip, a conductive glue being printed to the periphery of the chip, and being electrically connected to the second ground point, since the chip mounted on the upper surface of the substrate, the plurality of bonding pads of the chip being exposed via the long slot of the substrate, also a part of conductive glue exposed from the long slot of the substrate;
a plurality of wires, which are located within the long slot of the substrate, each of which having first terminal and second terminal, wherein the first terminals being electrically to the bonding pads and conductive glue, and second terminals being electrically connected to the connect points and first ground point of the substrate; and
a glue layer for sealing the chip and filling into the long slot of the substrate for protecting the chip and the plurality of wires.

2. The chip package structure according to claim 1, wherein the chip has two second ground points (VSS), also the substrate has two first ground points (VSS) for electrically connecting to the second ground point via the plurality of wires.

3. The chip package structure according to the claim, wherein the chip may be a DRAM.
